(19) United States
(12) Patent Application Publication
(10) Pub. No.: US 2011/0168238 A1
(43) Pub. Date: Jul. 14, 2011

(54) FLEXIBLE SOLAR MODULES AND MANUFACTURING THE SAME

(75) Inventors: Burak Metin, San Jose, CA (US); Eric Lee, San Jose, CA (US); Mustafa Pinarbasi, Morgan Hill, CA (US); Deepak Nayak, Fremont, CA (US)

(73) Assignee: SoloPower, Inc., San Jose, CA (US)

(21) Appl. No.: 12/972,367

(22) Filed: Dec. 17, 2010

Related U.S. Application Data
(63) Continuation-in-part of application No. 12/685,540, filed on Jan. 11, 2010.

(51) Int. Cl. H01L 31/048

(52) U.S. Cl. 136/251

(57) ABSTRACT

A flexible solar cell assembly having solar cells that are positioned within a sealed module chamber. A sealed wiring chamber is positioned on an end of the sealed module chamber and is interposed between the sealed module chamber and a junction box. Wiring interconnecting the junction box to the solar cells in the sealed module chamber are routed through the sealed wiring chamber to inhibit water entry into the sealed module chamber via the wiring.

### CROSS-REFERENCE TO RELATED APPLICATIONS

This application is a continuation in part of U.S. application Ser. No. 12/685,540 filed Jan. 11, 2010, entitled RELIABLE THIN FILM PHOTOVOLTAIC MODULE STRUCTURES, which is hereby incorporated in its entirety by reference herein.

### BACKGROUND

1. Field of the Inventions

The aspects and advantages of the present inventions generally relate to apparatus and methods of photovoltaic or solar module design and fabrication and, more particularly, to roll-to-roll or continuous packaging techniques for flexible modules employing thin film solar cells.

2. Description of the Related Art

Solar cells are photovoltaic (PV) devices that convert sunlight directly into electrical energy. Solar cells can be based on crystalline silicon or thin films of various semiconductor materials, that are usually deposited on low-cost substrates, such as glass, plastic, or stainless steel.

Thin film based photovoltaic cells, such as amorphous silicon, cadmium telluride, copper indium diselenide or copper indium gallium diselenide based solar cells, offer improved cost advantages by employing deposition techniques widely used in the thin film industry. Group IBIIIAVIA compound photovoltaic cells including copper indium gallium diselenide (CIGS) based solar cells have demonstrated the greatest potential for high performance, high efficiency, and low cost thin film PV products.

As illustrated in FIG. 1, a conventional Group IBIIIAVIA compound solar cell 10 can be built on a substrate 11 that can be a sheet of glass, a sheet of metal, an insulating foil or web, or a conductive foil or web. A contact layer 12 such as a molybdenum (Mo) film is deposited on the substrate as the back electrode of the solar cell. An absorber thin film 14 including a material in the family of Cu(In,Ga)(S,Se)₂, is formed on the conductive Mo film. The substrate 11 and the contact layer 12 form a base layer 13. Although there are other methods, Cu(In,Ga)(S,Se)₂ type compound thin films are typically formed by a two-stage process where the components (components being Cu, In, Ga, Se and S) of the Cu(In,Ga)(S,Se)₂ material are first deposited onto the substrate or the contact layer formed on the substrate as an absorber precursor, and are then reacted with S and/or Se in a high temperature annealing process.

After the absorber film 14 is formed, a transparent layer 15, for example, a CdS film, a ZnO film or a CdS/ZnO film-stack is formed on the absorber film 14. Light enters the solar cell 10 through the transparent layer 15 in the direction of the arrows 16. The preferred electrical type of the absorber film is p-type, and the preferred electrical type of the transparent layer is n-type. However, an n-type absorber and a p-type window layer can also be formed. The above described conventional device structure is called a substrate-type structure. In the substrate-type structure light enters the device from the transparent layer side as shown in FIG. 1. A so called superstrate-type structure can also be formed by depositing a transparent conductive layer on a transparent superstrate such as glass or transparent polymeric foil, and then depositing the Cu(In,Ga)(S,Se)₂ absorber film, and finally forming an ohmic contact to the device by a conductive layer. In the superstrate-type structure light enters the device from the transparent superstrate side.

In standard CIGS as well as Si and amorphous Si module technologies, the solar cells can be manufactured on flexible conductive substrates such as stainless steel foil substrates. Due to its flexibility, a stainless steel substrate allows low cost roll-to-roll solar cell manufacturing techniques. In such solar cells built on conductive substrates, the transparent layer and the conductive substrate form the opposite poles of the solar cells. Multiple solar cells can be electrically interconnected by stringing or shingling methods that establish electrical connection between the opposite poles of the solar cells. Such interconnected solar cells are then packaged in protective packages to form solar modules or panels. Many modules can also be combined to form large solar panels. The solar modules are constructed using various packaging materials to mechanically support and protect the solar cells contained in the packaging against mechanical damage. Each module typically includes multiple solar cells which are electrically connected to one another using the above mentioned stringing or shingling interconnection methods.

In standard silicon, CIGS and amorphous silicon cells that are fabricated on conductive substrates such as aluminum or stainless steel foils, the solar cells are not deposited or formed on the protective sheet. Such solar cells are separately manufactured, and the manufactured solar cells are electrically interconnected by a stringing or shingling process to form solar cell circuits. In the stringing or shingling process, the (+) terminal of one cell is typically electrically connected to the (−) terminal of the adjacent solar cell. For the Group IBIIIAVIA compound solar cell shown in FIG. 1, if the substrate 11 is a conductive material such as a metallic foil, the substrate, which forms the bottom contact of the cell, becomes the (+) terminal of the solar cell. The metallic grid (not shown) deposited on the transparent layer 15 is the top contact of the device and becomes the (−) terminal of the cell. When interconnected by a shingling process, individual solar cells are placed in a staggered manner so that a bottom surface of one cell, i.e. the (+) terminal, makes direct physical and electrical contact to a top surface, i.e. the (−) terminal, of an adjacent cell. Therefore, there is no gap between two shingled cells. Stringing is typically done by placing the cells side by side with a small gap between them and using conductive wires or ribbons that connect the (+) terminal of one cell to the (−) terminal of an adjacent cell. Solar cell strings obtained by stringing or shingling individual solar cells are interconnected to form circuits. Circuits may then be packaged in protective packages to form modules. Each module typically includes a plurality of strings of solar cells which are electrically connected to one another.

Generally, the most common packaging technology involves lamination of circuits in transparent encapsulants. In a lamination process, in general, the electrically interconnected solar cells are covered with a transparent and flexible encapsulant layer. A variety of materials are used as encapsulants, for packaging solar cell modules, such as ethylene vinyl acetate copolymer (EVA), thermoplastic polyurethanes (TPU), and silicones. However, in general, such encapsulant materials are moisture permeable; therefore, they must be further sealed from the environment by a protective shell, which provides resistance to moisture transmission into the module package.

The nature of the protective shell determines the amount of water that can enter the package. The protective shell includes a front protective sheet through which light enters the module and a back protective sheet and optionally an edge sealant that is at the periphery of the module structure. The top protective sheet is typically transparent glass which is water impermeable. The back protective sheet may be a sheet of glass or a polymeric sheet of TEDLAR® (a product of DuPont) and polyeyhylene teraphthalate (PET). The back protective polymeric sheet may or may not have a moisture barrier layer in its structure such as a metallic film like an aluminum film. The edge sealant is a moisture barrier material that may be in the form of a viscous fluid which may be dispensed from a nozzle to the peripheral edge of the module structure or it may be in the form of a tape which may be applied to the peripheral edge of the module structure.

A junction-box is typically attached on the exposed surface of the back protective sheet, right below the interconnected solar cells, using moisture barrier adhesives. Terminals of the interconnected solar cells are typically connected to the junction box through holes formed in the back protective sheet. In this way, the size of the module can be reduced as the frame holding the cells can be positioned very close to the solar cells. The holes in the back protective sheet must be very carefully sealed against moisture leakages using, for example, potting materials such as silicone, epoxy, butyl, and urethane containing materials. If the seal in the holes fails, such holes allow moisture to enter the module and can cause device failures.

Thin film solar cells are more moisture sensitive than the crystalline Si devices; therefore, materials with moisture barrier characteristics need to be used in the module structure and any potential moisture sources such as holes in the back and front protective sheets are problematic. For a flexible module to last 25 years, all the packaging components are also required to preserve mechanical, thermal, and chemical stability at the outdoors. The front protective sheet for thin film devices can be either glass or a flexible sheet depending on the product design requirements. A flexible front sheet can be composed of a combination of one or more weatherable films, such as fluoropolymers, for example, ETFE (ethylene-tetrafluoroethylene) or FEP (fluoro ethylene propylene) or polyvinylidene fluoride (PVDF) and a transparent inorganic moisture barrier layer such as Al₂O₃ or SiO₂. In one product, a weatherable film (ETFE, FEP or PVDF) can be laminated onto one or more inorganic moisture barrier layers to form a front protective sheet. However, during the lamination, stresses resulting from UV exposure, temperature cycle and humidity can deteriorate the front protective sheet which can result in severe inorganic moisture barrier-layer delaminations from the weatherable films. One can alleviate these problems by first incorporating the inorganic barrier layers onto a carrier film like poly(ethylene teraphthalate) PET and poly(ethylene naphthalate) PEN and then applying the weatherable film onto the carrier film instead of the barrier layer. Such carrier polymers are thermally and mechanically more stable. Although PET and PEN films are not as weatherable as the ETFE and FEP films, any temperature cycling on the solar panel would not impose as much stress as it would on a fluoropolymer like ETFE, FEP.

Weatherable films can also be incorporated into the moisture barrier layer-carrier film combinations using various adhesives. The adhesion of the weatherable film to the adhesives and adhesives to the moisture barrier layer-carrier film becomes very critical. As mentioned above, fluoropolymers are known to be very difficult to adhere to. For a target 25 years of life time, one would need a very strong adhesion among the layers of weatherable film-adhesive-moisture barrier layer-carrier film. If the adhesion is weak on one of the interfaces, the reliability of the whole product will be in question as any delamination can continue to propagate.

The weakness of the adhesion among the layers of the front protective sheet can also be problematic for junction box adhesion to the front protective sheet. Junction boxes conventionally have been attached to back side of the modules and on the back protective sheet, which is made of glass or TEDLAR due to the restrictions on the type of rigid solar panel installations. For a flexible module, there are implementations where the junction boxes should be attached on the front, especially when the modules are required to be incorporated on to the roof top membranes. However, once the junction box is placed on the front surface of a flexible module, there are adhesion issues with the ETFE and FEP fluoropolymers as explained above, and extra processes step (performed at additional cost) may be needed to improve adhesion between the top of the weatherable film and the junction box sealant or tape. Further, the weaker adhering front sheet layers are more likely to delaminate where the junction box is placed due to stress mismatches between the solar panel and the junction box. The delamination of one of the front sheet layers around the junction box area can create safety hazards as water can penetrate through the delaminated areas and touch live wires inside the junction box.

As the brief discussion above demonstrates, there is a need to develop new module structures, especially for thin film solar cells, to eliminate aforementioned problems while minimizing moisture permeability.

### SUMMARY

The aspects and advantages of the present inventions generally relate to apparatus and methods of flexible photovoltaic or solar module and panel design and fabrication. The aforementioned needs are satisfied by one embodiment of the invention that comprises a flexible solar power apparatus, comprising a flexible bottom sheet of a first material having a front surface and a back surface, the flexible bottom sheet including a first portion including a first front surface region and a second portion including a second front surface region. This apparatus further comprises at least one sealed module chamber, including a solar cell circuit with interconnected solar cells, formed over the first front surface region of the first portion, and a sealed wire chamber formed over the second front surface region, wherein a peripheral edge seal wall applied along the periphery of the flexible bottom sheet seals the outer edges of both the at least one sealed module chamber by a first portion of the peripheral edge seal wall and also the sealed wire chamber by a second portion of the peripheral edge seal wall, wherein an inner seal wall separates the sealed module chamber and the sealed wire chamber; and wherein a first flexible top sheet of a second material disposed on the first portion of the peripheral edge seal wall and the inner seal wall thereby enclosing a light receiving side of the at least one sealed module chamber, and wherein a second flexible top sheet of the first material is disposed on the second portion of the peripheral edge seal wall and the inner seal wall thereby enclosing the sealed wire chamber. This embodiment comprises a junction-box formed over the second flexible top sheet of the sealed wire chamber, wherein terminal wires of the solar cell circuit are extended from the at least one sealed module to the junction box through the sealed wire chamber.

In another embodiment, the present invention comprises a flexible solar panel, comprising a bottom protective sheet of a first material and a front protective sheet placed over the bottom protective sheet, the front protective sheet including a first section of a first material and a second section of a second material placed adjacent to the first section along an interface, wherein the first material is a transparent material and wherein the moisture resistance of the second material is greater than the first material. In this embodiment, the invention further comprises an edge moisture sealant wall formed between the bottom protective sheet and the front protective sheet along the perimeters of the bottom and the front protective sheet, thereby sealing the perimeters of the bottom protective sheet and the front protective sheet against moisture. In this embodiment, the invention further comprises an inner moisture sealant wall formed between the front protective sheet and the bottom protective sheet and along the interface and between the first section and the second section of the front protective sheet, thereby forming a sealed module chamber under the first section and a sealed wire chamber under the second section. In this embodiment, the invention further comprises a junction box is attached to the wire chamber to connect the flexible solar panel to a power circuitry; wherein a solar cell circuit including a plurality of interconnect solar cells is disposed in the sealed module chamber, and terminal wires of the solar cell circuit is extended from the sealed module chamber to the junction box through the sealed wire chamber.

In another embodiment, the invention comprises a flexible solar panel comprising a sealed module chamber having a first surface and a second surface, wherein the first surface is transparent to permit light to enter the sealed module chamber and wherein the sealed module chamber defines a first and a second end having end walls. In this embodiment, the invention further comprises a plurality of solar cells positioned within the sealed module chamber wherein the plurality of solar cells has at least one wire that transmits energy from the plurality of solar cells to an external recipient of the energy. In this embodiment, the invention comprises a sealed wiring chamber having outer surfaces that is attached adjacent to a first end of the sealed module chamber so that an end wall of the sealed module chamber defines an inner seal wall and wherein the at least one wire extends through the sealed wiring chamber. In this embodiment, the invention further comprises a junction box that is attached to one of the outer surfaces of the sealed wiring chamber, wherein the junction box receives the at least one wire from the sealed wiring chamber and permits electrical interconnection between the at least one wire and the external recipient of energy.

These and other objects and advantages of the present invention will become more apparent from the following description taken in conjunction with the accompanying drawings.

### BRIEF DESCRIPTION OF THE DRAWINGS

FIG. 1 is a schematic view a thin film solar cell;

FIG. 2A is a schematic cross sectional view of a flexible thin film solar panel;

FIG. 2B is a schematic cross sectional view of the flexible solar panel shown in FIG. 2A;

FIGS. 3-4 are schematic views of various embodiments of the auxiliary unit and the junction box of the flexible panel; and

FIGS. 5-6 are schematic views of various alternative embodiments of a flexible solar panel.

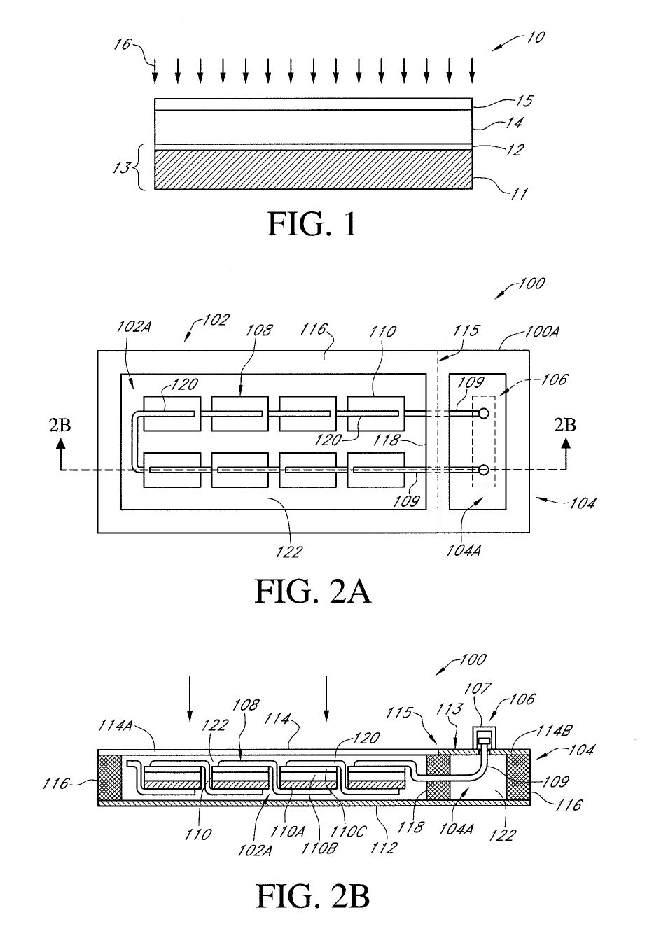

### DETAILED DESCRIPTION OF THE PREFERRED EMBODIMENTS

The preferred embodiments described herein provide methods of manufacturing flexible photovoltaic power apparatus or solar panel including one more flexible solar modules employing interconnected thin film solar cells, preferably Group IBIIIAVIA compound solar cells. The photovoltaic power apparatus or solar panel preferably includes a sealed module chamber with a first top protective sheet and a sealed wire chamber with a second top protective sheet. A connection box or a junction box through which the apparatus is connected to a power circuitry may be attached to the sealed wire chamber so that the terminal wires of the interconnected solar cells are extended from the sealed module chamber to the junction box through the sealed wire chamber.

The first top protective sheet is a transparent light receiving top protective sheet. The second top protective sheet is different from the first top protective sheet of the sealed module chamber. The second top protective sheet may be a high moisture resistive material and may not be transparent to visible light. The first and second top protective sheets form the front side of the solar panel, which may be manufactures as a single piece with the first and second top protective sheet portions or by attaching the second protective sheet to the first top protective sheet using various bonding and sealing methods.

The chambers may be formed side by side and separated from one another by a common sealant wall or abutted individual sealant walls belonging to the chambers. Both chambers may be formed on the same back protective sheet or different back protective sheets. In either case, the first and second top protective sheets form the front side of the solar panel. In the preferred embodiment, the second top protective sheet covering the wire chamber includes the same material as the back protective sheet and the junction box is placed on the wire chamber by attaching it to the second top protective sheet As described above in the background, in rigid and flexible module structures employing thin film solar cells, it is important to minimize moisture permeability of the module structure while assuring that the structure passes the electrical safety tests necessary for safe operation in the field. In one embodiment, the current invention is related to a method for a flexible module design where the junction box is on the front side of a solar module and is attached to a back sheet material that is not as hard to adhere as the weatherable ETFE, FEP films. In another embodiment, the current invention also provides unique dielectric materials and lay-up structure to inhibit any electrical wet leakage failures. Both advantages bring the improved reliability and safety for the flexible solar panel to enhance its ability to last at least 25 years.

Reference will now be made to the drawings wherein like numerals refer to like parts throughout. FIG. 2A shows in plan view an embodiment of a flexible solar panel 100 of the present invention.

The flexible solar panel may comprise a module 102 having a module housing 102A, a flexible auxiliary unit 104 including a auxiliary unit housing 104A and a junction-box 106 or connection housing attached to the auxiliary unit 104. A solar power generating solar cell circuit 108 is held in the module housing 102A. As will be explained more fully below, terminal leads 109 of a solar cell circuit 108 is extended from the module 102 to the junction box 106 through the auxiliary unit 104 in a well sealed manner while inhibiting any moisture seepage into the module housing. In this configuration, the auxiliary unit 104 forms a buffer zone between the module 102 and the junction box 106, which additionally seals the terminal leads 109 exiting the module 102 and entering junction box. Although in this embodiment the flexible solar panel 100 is exemplified with the module 102, the auxiliary unit 104 and the junction box 106; the flexible solar panel 100 of the present invention may have multiple modules with a single auxiliary unit or multiple auxiliary units as well as single or multiple junction boxes.

As shown in FIG. 2A in top view and in FIG. 2B in cross sectional side view, the flexible solar module has a flexible outer shell 100A that may be made of a bottom flexible protective sheet 112, a top flexible protective sheet 114, and a peripheral sealant wall 116 extending between the bottom and top flexible protective sheets and applied along the perimeter of them. An inner seal wall 118 divides the interior space of the shell into two, as the module housing and the auxiliary unit housing in which the components of the respective housings are placed. The peripheral sealant wall 116 may be made of a viscous moisture barrier sealant or a moisture barrier sealant tape. An exemplary material for the peripheral sealant and the inner seal walls may be butyl rubber with desiccants having 5 to 13 mm width and 0.5 mm to 1.5 mm thickness.

The solar cell circuit 108 includes a number of solar cells 110 interconnected using a stringing technique that employs conductive leads 120, such as conductive wires or ribbons, to electrically connect the solar cells, preferably in series. However, the solar cell circuit 108 may also be formed using shingling techniques to interconnect the solar cells 110 without using conductive leads, such shingling principles are described above in the background section. Each solar cell 110 generally includes a substrate 110A, an absorber layer 110B formed over the substrate and a transparent layer 110C formed over the absorber layer 110B. The absorber layer 110B may be a Group IBIIIAVIA absorber layer such as a Cu(In, Ga) Se₂ compound layer. The substrate 110A may be a flexible foil substrate such as a stainless steel foil or an aluminum foil. There may be a back contact layer (not shown), such as a molybdenum layer between the substrate and the absorber layer. A current collecting structure (not shown) including a busbars and fingers is deposited onto a top surface of the transparent layer 110C, which is also the light receiving side of the solar cells. A support material 122 or encapsulant, such as ethylene vinyl acetate (EVA) and/or thermoplastic polyurethane (TPU), and thermoplastic polyolefins, fills the space surrounding the solar cell circuit 108 in the module housing. The support material 122 is a transparent material which fills any hollow space among the cells and tightly seals them into a module structure by covering their surfaces. The conductive leads 120 are connected to the solar cell strings using methods which are well known in the solar cell manufacturing technologies.

In this embodiment, the top flexible protective sheet 114 may comprise a first section 114A including a first material and a second section 114B including a second material. As shown in FIGS. 2A and 2B, the first section 114A of the top protective sheet forms top of the module 102 and the second section 114B forms top of the auxiliary unit 104. An intersection 115 separating the first and second sections 114A, 114B are placed adjacent top of the inner seal 118 between the module housing 102A and the auxiliary unit housing 104A. The junction box 106, preferably a junction box enclosure 107, is preferably attached to a top surface 113 of the second section 114B of the top flexible protective sheet 114 covering the auxiliary unit housing 104A. The first material of the first section 114A may be different from the second material of the second section 114B, or at least the material of the top surface 113 of the second section, of the top flexible protective sheet 114 of the flexible solar panel 100. The first and the second materials may be sheet materials including single or multiple material layers. As will be described more fully below, the second material of the second section 114B may be the same as the material of the bottom protective sheet 112 or another material having a top surface that is more compatible with the sealants or adhesives used to attach the junction box to the second section surface. The first section 114A and the second section 114B may be separate pieces that brought together and sealed along the interface 115. Alternatively, the first and the second sections may be integrated and manufactured together as a single top flexible protective sheet. Of course, the second section may also include the material of the first section. In this particular case, an inner surface of the second section (the surface facing towards the auxiliary unit housing) may preferably be treated with a moisture sealant layer.

In modules employing thin film devices, such as thin film CIGS solar cells, it is important that the bottom protective sheets be a moisture barrier. The bottom flexible protective sheet 112 of the flexible solar panel 100 may typically be a polymeric sheet having moisture barrier characteristics such as TEDLAR®, a polyvinyl fluoride PVF film available from DuPont, Inc., or other polymeric sheet materials such as PVDF (Poly vinyledene difluoride), PET (poly ethylene teraphtalate), Perfluoro-alkyl vinyl ether, PA (polyamide) or PMMA (poly methyl methacrylate). The flexible bottom protective sheet 112 may be non-transparent sheet and may preferably comprise a composite structure, i.e., multiple layers stacked and bonded, including one or more metallic layers such as aluminum layers between the polymeric sheets to further improve moisture resistance of the bottom flexible protective sheet. The metallic layer, or moisture barrier, may be interposed between polymeric sheets such as TEDLAR® layers or other polymeric material layers so that the polymeric sheet forms the outer surface exposed to outside. For example, when a 18 to 50 um thick aluminum (Al) sheet is laminated into the structure of such TEDLAR sheets, very low water vapor transmission rates of 10⁻³ g/m²/day or lower can be achieved. In addition to its high moisture barrier property, TEDLAR exhibits good adhesion to the sealants used to adhere junction box or other module components to TEDLAR surfaces. TEDLAR forms moisture resistant seals with such a sealant used to attach junction boxes 107 to TEDLAR surfaces. An exemplary flexible bottom protective sheet may include the structure of a top TEDLAR layer/Aluminum layer/PET layer/Primer and may have a thickness of about 0.4 mm. When the same material is used for the second section 114B of the top flexible protective sheet 114, the auxiliary unit 104 becomes more moisture resistant and moisture transmission through the path ways of terminal wires 109 is reduced.

Thus, the second section 114B of the top flexible protective sheet may be made of any polymeric sheet or polymeric-metal sheet combinations. The top surface 113 of the second section may be a polymeric back sheet material such as TEDLAR, PVDF, PET, Perfluoro-alkyl vinyl ether, PA or PMMA. The junction box 106 on the solar module can be located on the second section 114B of the top flexible protective sheet 114 as shown in FIGS. 2A and 2B and attached to the polymeric materials on the top surface 113. It is easier to adhere the junction box to this material than the weatherable ETFE, FEP films that are mentioned in the background section. The flexible bottom protective sheet 112 as well as the second section 114B of the flexible top protective sheet 114 may at least include an outer polymeric layer, such as TEDLAR, covering a non-transparent inorganic moisture barrier layer such as a metallic layer, for example Al. The junction box enclosure 107 may be made of Noryl, PPE (poly phenylene ether), PET, Nylon, Polycarbonate, or PPE with PS (poly styrene) materials. Exemplary adhesive that can be used to attach the junction box to the top surface 113 of the second section 114B may be silicone sealants such as Dow Corning PV804, Shinetsu KE220/CX220, Tonsan 15276 or adhesive tapes like 3M VHB 5952, Duplomont 9182. The adhesive tapes may need a primer to apply them to the surface materials.

Exemplary flexible and transparent materials for the first section 114A of the top flexible protective sheet may include ethylene tetrafluoroethylene (ETFE) under TEFZEL® commercial name or fluorinated ethylene propylene (FEP) from DuPont or poly vinylidene fluoride (PVDF) under KYNAR commercial name. The first section 114A may at least include an outer polymeric layer, such as ETFE, FEP or PVDF, covering a transparent inorganic moisture barrier layer such as Al₂O₃ or SiO₂. As explained above, although such materials are very weather-resistant materials, they have weaker adhesion to the junction box sealants (Silicone based one or two component systems, with room temperature cure chemistry) and VHB type tapes used to attach junction box to the modules, and the lack of any inorganic moisture barrier layer or foil make them more vulnerable against the moisture. The moisture transmission rate of an ETFE or FEP front sheet is around 1 to 10 g/m²/day. An exemplary first section of the top protective sheet may include the structure of a top FEP, ETFE or PVDF layer/Adhesive film/Moisture barrier-Carrier film and may have a thickness in the range of 0.1 to 0.15 mm. As described in the background section, the carrier film may include PET poly(ethylene teraphthalate) and PEN poly(ethylene naphthalate). An exemplary transparent moisture barrier material may include Al₂O₃ or SiO₂.

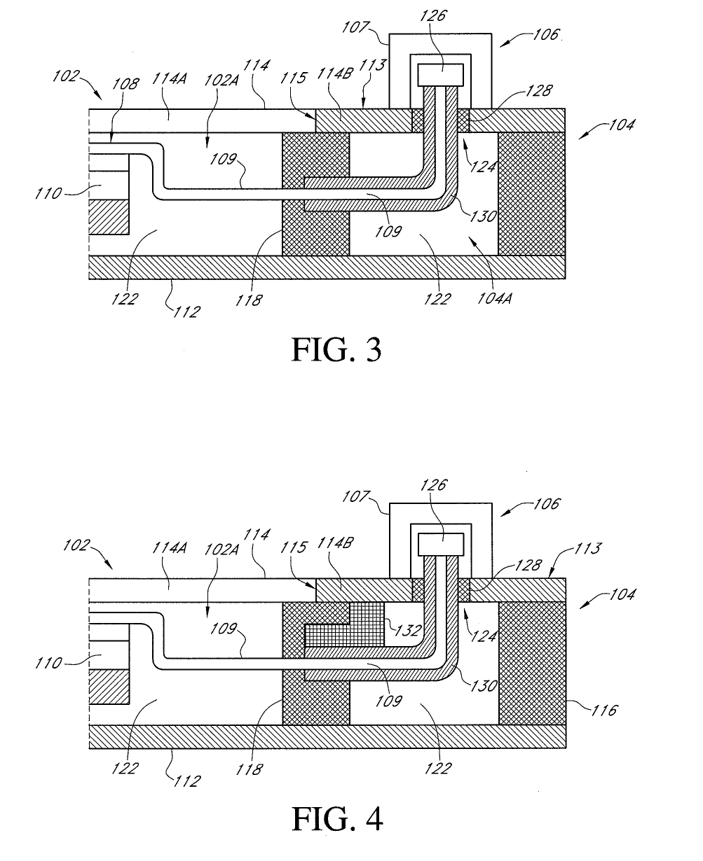

FIGS. 3 and 4 schematically illustrate various manners in which the auxiliary unit 104 and the junction box 106 of the flexible solar panel shown in FIGS. 2A and 2B are constructed.

In the embodiment shown in FIG. 3, the terminal wires 109 pass through the inner seal wall 118 and enters the auxiliary unit housing 104A, and then through openings 124 in the second section 114B of the top flexible protective sheet 114, connected to terminals 126 in the junction box 106. To reduce any moisture leakage in the auxiliary housing, a seal material 128 may be used to seal the holes 124. As described above, the junction box enclosure 107 is sealably attached to the top surface 113 of the second section 114B, which further encloses the openings 124. The portion of the terminal wires 109 extending from the inner seal wall 118 may be coated with a protective shield 130 made of a high dielectric strength and moisture resistant material. One end of the protective shield may be embedded into the inner seal wall 118, and the other end may extend into the junction box 106. The protective shield 130 may be formed and applied as a shrink tube and may be placed through the opening 128 in a tightly fitting manner to further minimize any moisture leakage inside the auxiliary housing 104A. Exemplary materials for the protective shield 130 may be the following materials: polyethylene terephthalate (PET), which is available under the commercial names Mylar, Melinex, heat shrink Mylar; polyimide (Kapton); polyolefins (EPS 300); and polyethylene napthalate (PEN).

As shown in FIG. 3 the intersection 115 between the first and second sections 114A, 114B may be located over the inner seal wall 118. However there may be other insulating and moisture resistant layers between top of the inner seal wall 118 and the intersection 115 if the first and second sections made of separate pieces.

As shown in FIG. 4, an insulating film 132, used with the inner seal wall 118, mechanically and electrically supports the second section 114B, when the top flexible protective sheet 114 is comprised of two different pieces and when only the edge of the first section 114A is placed on the inner seal wall 118. The insulating film 132 may include a high dielectric PET layer and adhesives on both sides to improve adhesion to the materials in contact. The dielectric constant of PET is equal or greater than 11 kV/mil and it preserves its electrical properties even with moisture penetration. There will be a potential difference between the live wires and the water that penetrates through the intersection 115 during a rainy season. This potential difference can be up to 1000 V DC. The material used as the insulating film 132 must be tested against partial discharge tests as not every material can withstand the 1000 V partial discharge tests without compromising its insulating electrical properties. EPE film from Madico Inc. of Woburn, Mass. is one of these materials that is available commercially. PET thickness may vary from 2 mil to 5 mil and adhesive thickness may be 2 to 4 mil on both sides. In this configuration, the insulating film 132 prevents any water leakage and electrical leakage through the intersection 115. The intersection 115 may open up and widen during installation or due to temperature cycling on the field, and rubbery edge seal under the intersection 115 may break apart exposing the live wires to the water and moisture penetration. With the high dielectric strength insulating film 132 in place, there will be no electrical leakage from wires to the water and moisture penetrated through openings. The insulating film 132 also provides mechanical support for the junction box pocket as the intersection 115 is weak for any bending stress.

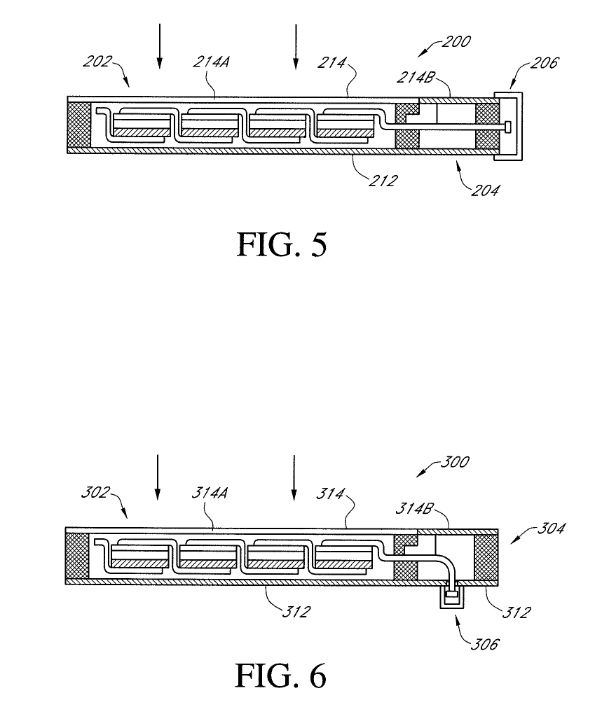

FIGS. 5 and 6 illustrate alternative locations for the junction box. As shown in FIG. 5, in a flexible solar panel 200 comprising a module 202, auxiliary unit 204 and a junction box 206, the junction box 206 may be attached to a side of the auxiliary unit. The solar panel 200 includes: a flexible top protective sheet 214 including a first section 214A which is transparent, and a second section 214B; and a flexible bottom protective sheet 212. In this embodiment, the junction box is attached to the outer surfaces of flexible bottom protective sheet 212 and the second section 214B of the flexible top protective sheet that may include the same material, as described in the above embodiments. As shown in FIG. 6, in a flexible solar panel 300 comprising a module 302, auxiliary unit 304 and a junction box 306, the junction box 306 may be attached to the bottom of the auxiliary unit 304. The solar panel 300 includes: a flexible top protective sheet 314 including a first section 314A, which is transparent, and a second section 314B; and a flexible bottom protective sheet 312. In this embodiment, the junction box 306 is attached to the outer surface of flexible bottom protective sheet 312.

Although aspects and advantages of the present inventions are described herein with respect to certain preferred embodiments, modifications of the preferred embodiments will be apparent to those skilled in the art. The scope of the present invention should not be limited to the foregoing discussion but should be defined by the appended claims.

We claim:

1. A flexible solar power apparatus, comprising:
a flexible bottom sheet of a first material having a front surface and a back surface, the flexible bottom sheet including a first portion including a first front surface region and a second portion including a second front surface region;
at least one sealed module chamber, including a solar cell circuit with interconnected solar cells, formed over the first front surface region of the first portion, and a sealed wire chamber formed over the second front surface region, wherein a peripheral edge seal wall applied along the periphery of the flexible bottom sheet seals the outer edges of both the at least one sealed module chamber by a first portion of the peripheral edge seal wall and also the sealed wire chamber by a second portion of the peripheral edge seal wall, wherein an inner seal wall separates the sealed module chamber and the sealed wire chamber; and wherein a first flexible top sheet of a second material disposed on the first portion of the peripheral edge seal wall and the inner seal wall thereby enclosing a light receiving side of the at least one sealed module chamber, and wherein a second flexible top sheet of the first material is disposed on the second portion of the peripheral edge seal wall and the inner seal wall thereby enclosing the sealed wire chamber; and
a junction-box formed over the second flexible top sheet of the sealed wire chamber, wherein terminal wires of the solar cell circuit are extended from the at least one sealed module to the junction box through the sealed wire chamber.

2. The apparatus of claim 1, wherein the first flexible top sheet is transparent to visible light.

3. The apparatus of claim 2, wherein the first flexible top sheet includes a polymeric outer layer covering an inorganic transparent moisture barrier layer.

4. The apparatus of claim 3, wherein the polymeric outer layer includes one of ETFE (ethylene-tetrafluoroethylene), FEP (fluoro ethylene propylene) and PVDF (poly vinylidene fluoride).

5. The apparatus of claim 3, wherein the inorganic transparent moisture barrier layer includes one of aluminum oxide or silicon oxide.

6. The apparatus of claim 1, wherein the at least one sealed module chamber includes an encapsulant material coating the solar cells and filling the rest of the at least one sealed module chamber.

7. The apparatus of claim 1, wherein the terminal wires include a moisture resistant and insulating tubing.

8. The apparatus of claim 7, wherein the terminal wires extended through the inner seal wall.

9. The apparatus of claim 7, wherein the inner seal wall includes a top sealant layer and a bottom sealant layer and the terminal wires extended between the top and bottom sealant layers.

10. The apparatus of claim 9, wherein an insulation layer is disposed between the top sealant layer and the terminal wires.

11. The apparatus of claim 7, wherein the sealed wire chamber includes an encapsulant material coating the terminal wires and filling the rest of the at least one sealed module chamber.

12. The apparatus of claim 1, wherein both the flexible bottom sheet and the second flexible top sheet include a polymeric outer layer covering an inorganic non-transparent moisture barrier layer TEDLAR (polyvinyl fluoride).

13. The apparatus of claim 12, wherein the polymeric outer layer includes one of TEDLAR® (polyvinyl fluoride), PVDF (Poly vinyledene difluoride), PET (poly ethylene teraphtalate), Perfluoro-alkyl vinyl ether, PA (polyamide) and PMMA (poly methyl methacrylate).

14. The apparatus of claim 12, wherein the inorganic non-transparent moisture barrier layer includes a metal film.

15. The apparatus of claim 1, wherein the solar cells include Group IBIIIAVIA thin film solar cells.

16. A flexible solar panel, comprising:
a bottom protective sheet of a first material;
a front protective sheet placed over the bottom protective sheet, the front protective sheet including a first section of a first material and a second section of a second material placed adjacent to the first section along an interface, wherein the first material is a transparent material and wherein the moisture resistance of the second material is greater than the first material;
an edge moisture sealant wall formed between the bottom protective sheet and the front protective sheet along the perimeters of the bottom and the front protective sheet, thereby sealing the perimeters of the bottom protective sheet and the front protective sheet against moisture;
an inner moisture sealant wall formed between the front protective sheet and the bottom protective sheet and along the interface and between the first section and the second section of the front protective sheet, thereby forming a sealed module chamber under the first section and a sealed wire chamber under the second section; and
a junction box is attached to the wire chamber to connect the flexible solar panel to a power circuitry; and
wherein a solar cell circuit including a plurality of interconnect solar cells is disposed in the sealed module chamber, and terminal wires of the solar cell circuit is extended from the sealed module chamber to the junction box through the sealed wire chamber.

17. The apparatus of claim 16, wherein the first flexible top sheet is transparent to visible light.

18. The apparatus of claim 16, wherein the at least one sealed module chamber includes an encapsulant material coating the solar cells and filling the rest of the at least one sealed module chamber.

19. The apparatus of claim 16, wherein the terminal wires include a moisture resistant and insulating tubing.

20. The apparatus of claim 19, wherein the terminal wires extended through the inner seal wall.

21. The apparatus of claim 20, wherein the inner seal wall includes a top sealant layer and a bottom sealant layer and the terminal wires extended between the top and bottom sealant layers.

22. The apparatus of claim 21, wherein an insulation layer is disposed between the top sealant layer and the terminal wires.

23. The apparatus of claim 21, wherein the sealed wire chamber includes an encapsulant material coating the terminal wires and filling the rest of the at least one sealed module chamber.

24. The apparatus of claim 16, wherein both the flexible bottom sheet and the second flexible top sheet include TEDLAR (polyvinyl fluoride

25. The apparatus of claim 16, wherein the first flexible top sheet includes one of ETFE (ethylene-tetrafluoroethylene), FEP (fluoro ethylene propylene) and PVDF (poly vinylidene fluoride).

26. The apparatus of claim 16, wherein the solar cells include Group IBIIIAVIA thin film solar cells.

27. A flexible solar panel comprising:
a sealed module chamber having a first surface and a second surface, wherein the first surface is transparent to permit light to enter the sealed module chamber and wherein the sealed module chamber defines a first and a second end having end walls;
a plurality of solar cells positioned within the sealed module chamber wherein the plurality of solar cells has at least one wire that transmits energy from the plurality of solar cells to an external recipient of the energy;
a sealed wiring chamber having outer surfaces including a first and a second surface that is attached adjacent to a first end of the sealed module chamber so that an end wall of the sealed module chamber defines an inner seal wall between the chambers and wherein the at least one wire extends through the sealed wiring chamber;
a junction box that is attached to one of the outer surfaces of the sealed wiring chamber, wherein the junction box receives the at least one wire from the sealed wiring chamber and permits electrical interconnection between the at least one wire and the external recipient of energy.

28. The apparatus of claim 27, wherein the second surfaces of the sealed module chamber and the sealed wiring chamber includes a single piece of material that extends over the sealed module chamber and the sealed wiring chamber.

29. The apparatus of claim 28, wherein the single piece of material includes a metal layer which inhibits water entry into either the sealed module chamber or the sealed wiring chamber.

30. The apparatus of claim 29, wherein the first surface of the sealed module chamber and the sealed wiring chamber are positioned proximate to each other and wherein the single piece of material on the second surfaces of the sealed module chamber and the sealed wiring chamber extends onto the first surface of the sealed wiring chamber.

31. The apparatus of claim 27, wherein the sealed module chamber and the sealed wiring chamber further include an encapsulant to inhibit water entry into the chambers.

32. The apparatus of claim 27, further comprising insulating tubing that extends in the sealed wiring chamber from the inner seal wall to the outer wall proximate the junction box and wherein the at least one wire is positioned within the insulating tubing to inhibit water entry in the sealed module chamber via the at least one wire.

33. The apparatus of claim 27, wherein the junction box is positioned on the first surface of the sealed wiring chamber.

34. The apparatus of claim 27, wherein the junction box is positioned on an end wall of the sealed wiring chamber.

35. The apparatus of claim 27, wherein the junction box is positioned on the second surface of the sealed wiring chamber.

36. The apparatus of claim 27, wherein the portion of the inner seal wall adjacent the first surface of the sealed module chamber is formed of an insulating film.

37. The apparatus of claim 36, wherein the insulating film comprises a high dielectric PET layer.
